(19) United States
(12) Patent Application Publication
(10) Pub. No.: US 2007/0155151 A1
(43) Pub. Date: Jul. 5, 2007

(54) SEMICONDUCTOR DEVICE AND A MANUFACTURING METHOD

(76) Inventor: Sang-Il Hwang, Seoul (KR)

Correspondence Address: SHERR & NOURSE, PLLC, 620 HERNDON PARKWAY, SUITE 200, HERNDON, VA, 20170, US

(21) Appl. No.: 11/611,647

(22) Filed: Dec. 15, 2006

(30) Foreign Application Priority Data
Dec. 29, 2005 (KR) 10-2005-0134364

(51) Int. Cl. H01L 21/44

(52) U.S. Cl. 438/597

(57) ABSTRACT

A semiconductor device includes a first interlayer insulating film formed on a semiconductor substrate, a via exposing the substrate, a plug filling the via, a metal wiring layer on the first interlayer insulating film contacting the plug, and a second interlayer insulating film supported by the metal wiring and being partially suspended over the first interlayer insulating film, thereby forming an air gap. The second interlayer insulating film is provided with an aperture portion through which the first interlayer insulating film is exposed.

The present application claims priority under 35 U.S.C. 119 and 35 U.S.C. 365 to Korean Patent Application No. 10-2005-0134364 (filed on Dec. 29, 2005), which is hereby incorporated by reference in its entirety.

### BACKGROUND

As semiconductors achieve higher levels of integration and ever faster switching speeds, metal wiring layers formed within the semiconductor devices are getting finer and using multiple layers. However, as the widths of the metal wiring layers get reduced, signal delays may occur due to a resistance and parasitic capacitance (RC) of the metal wirings, thus impeding high speed switching and processing in semiconductor devices. Also, with an increase in leakage currents, power consumption increases.

To reduce such signal delays, copper wiring is employed instead of aluminum wiring. However, with the trend towards narrower wiring, parasitic capacitance between wiring increases, so that signal delays occur even using copper wiring. To reduce the problem of RC delays, an interlayer insulating film between the wirings using a low-k material may be used. As semiconductor devices get finer, a lower dielectric constant is required.

For this reason, an air gap, which has a dielectric constant lower than that of a low-k material, in the interlayer insulating film between the wirings may be used.

However, the structure of an insulating film with an air gap may be more complicated than an insulating film without an air gap. Thus, the process for forming the insulating film with an air gap may be relatively difficult.

### SUMMARY

Embodiments relate to a semiconductor device having a copper wiring layer. Embodiments relate to a method for manufacturing a semiconductor device having a copper wiring layer. Embodiments provide a relatively simple and relatively easy method for forming an insulating film having an air gap.

In accordance with embodiments, a semiconductor device includes: a semiconductor substrate; a first interlayer insulating film formed over the semiconductor substrate and provided with a via through which the semiconductor substrate is exposed; a plug connected to the semiconductor substrate through the via; a metal wiring layer formed over the first interlayer insulating film and being in contact with the plug; and a second interlayer insulating film supported by the metal wiring and being in a floating state over the first interlayer insulating film.

In accordance with embodiments, a method for forming a semiconductor device includes: forming a first interlayer insulating film over a semiconductor substrate; forming a via through the first interlayer insulating film; forming a plug by filling the via; forming a photoresist film over the first interlayer insulating film; forming a trench by performing an exposure and development of the photoresist film, the trench allowing the plug to be exposed therethrough; forming a metal wiring by filling the trench with a metal; forming a second interlayer insulating film over the metal wiring; forming a cutoff portion in the second interlayer insulating film, the cutoff portion allowing the photoresist film to be exposed there through; and removing the photoresist film through the cutoff portion.

In accordance with embodiments, a method for manufacturing a semiconductor device includes: forming a first interlayer insulating film on a semiconductor substrate; forming a via through the first interlayer insulating film; forming a photoresist film on the first interlayer insulating film; forming a trench by performing an exposure and development of the photoresist film, the trench allowing the plug to be exposed therethrough; forming a metal wiring by filling the trench and the via; forming a second interlayer insulating film on the metal wiring; forming a cutoff portion in the second interlayer insulating film, the cutoff portion allowing the photoresist film to be exposed therethrough; and removing the photoresist film trough the cutoff portion.

### BRIEF DESCRIPTION OF THE DRAWINGS

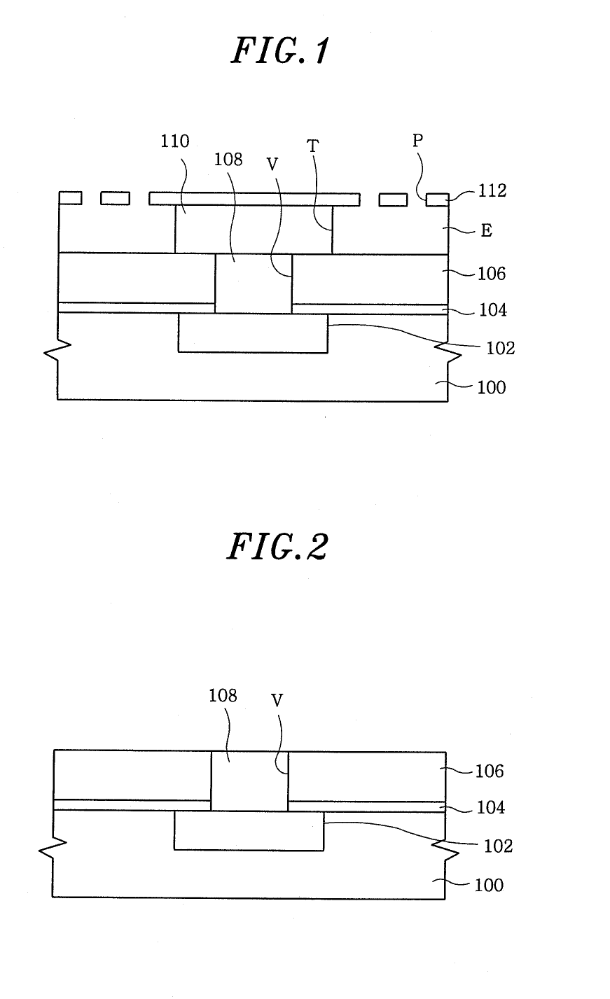

Example FIG. 1 is a cross sectional view of a semiconductor device, in accordance with embodiments.

Example FIGS. 2 to 5 illustrate cross sectional views showing methods for forming a semiconductor device, in accordance with embodiments.

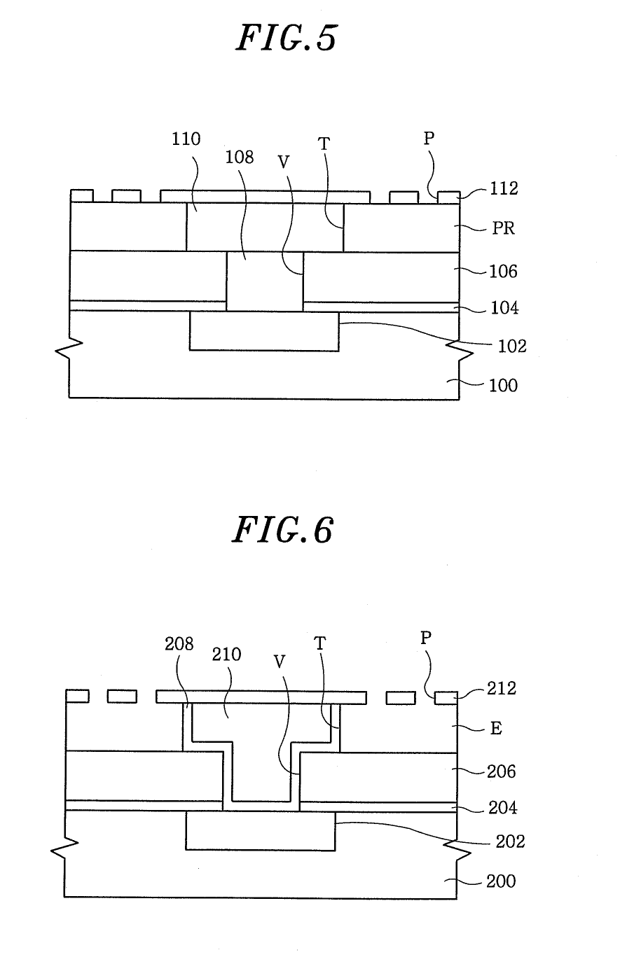

Example FIG. 6 is a cross sectional view of a semiconductor device in accordance with embodiments;

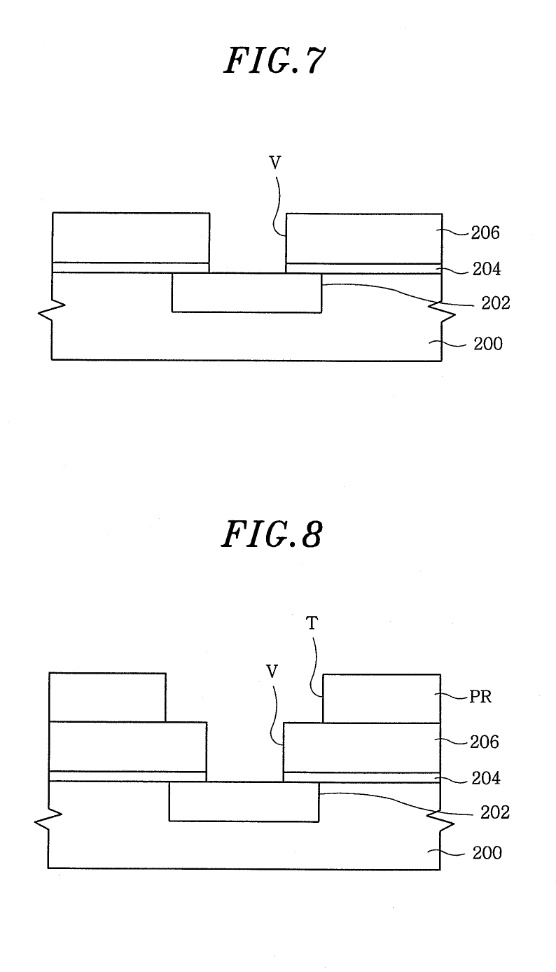

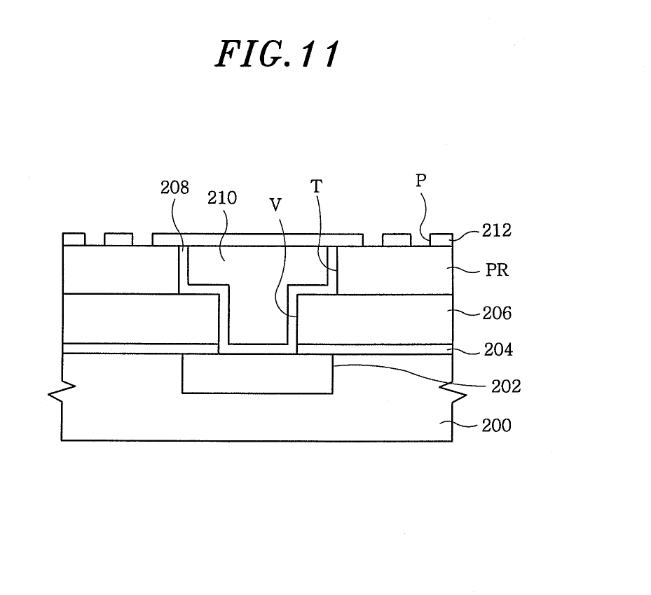

Example FIGS. 7 to 11 illustrate cross sectional views showing methods for forming a semiconductor device, in accordance with embodiments.

### DETAILED DESCRIPTION

Referring to FIG. 1, there is provided a cross sectional view of a semiconductor device, in accordance with embodiments. As shown in FIG. 1, an etching stop layer 104 and a first interlayer insulating film 106 are formed over a substrate 100. The substrate 100 may include individual devices (not shown) or a lower conductor 102.

The lower conductor 102 can be formed of copper (Cu), aluminum (Al), tungsten (W), silver (Ag), gold (Au), platinum (Pt), or the like. The etching stop layer 104 can be made of SiN or the like. The first interlayer insulating film 106 can be formed by depositing an organic or inorganic insulating material such as fluorine silicate glass (FSG), undoped silicate glass (USG), or tetra ethyl ortho silicate (TEOS), either in a single layer or multiple layers. Alternatively, the first interlayer insulating film 106 can also be formed of a low-k material such as a black diamond (BD) having a dielectric constant not greater than 3.0.

The lower conductor 102 of the substrate 100 is partially exposed by via V formed through the first interlayer insulating film 106. A plug 108 fills the via V and connects with the lower conductor 102. A metal wiring layer 110 is formed over the plug 108 and is in contact with the plug 108. The plug 108 is composed of, for example, tungsten (W) and thus serves to connect the lower conductor 102 and the metal wiring 110. The plug 108 and the metal wiring 110 may be formed of the same material.

A second interlayer insulating film 112 is formed on the metal wiring layer 110. The second interlayer insulating film 112 is in contact with the metal wiring 110 protruded over the first interlayer insulating film 106 but does not contact the first interlayer insulating film 106. Accordingly, the second interlayer insulating film 112 is partially suspended over the first interlayer insulating film 106 while being partially supported by the metal wiring 110. Thus, an empty space E exists between the first and the second interlayer insulating film 106 and 112.

The second interlayer insulating film 112 has aperture portions P through which the first interlayer insulating film 106 is partially exposed. With the empty space E between the first and the second interlayer insulating film 106 and 112 as described above, the dielectric constant of the semiconductor device decreases, so that parasitic capacitance can be reduced. The second interlayer insulating film 112 can be formed of a material such as SiN.

Below, a method for forming metal wiring of a semiconductor device having the described configuration will be explained with reference to FIGS. 2 to 5 together with FIG. 1.

FIGS. 2 to 5 provide cross sectional views to describe a method for forming the metal wiring of the semiconductor device in accordance with embodiments. As shown in FIG. 2, the etching stop layer 104 and the first interlayer insulating film 106 are deposited on the substrate 100. Then, the via V is formed through a selective etching process, and the plug 108 is formed by filling the via V with a metal such as tungsten (W).

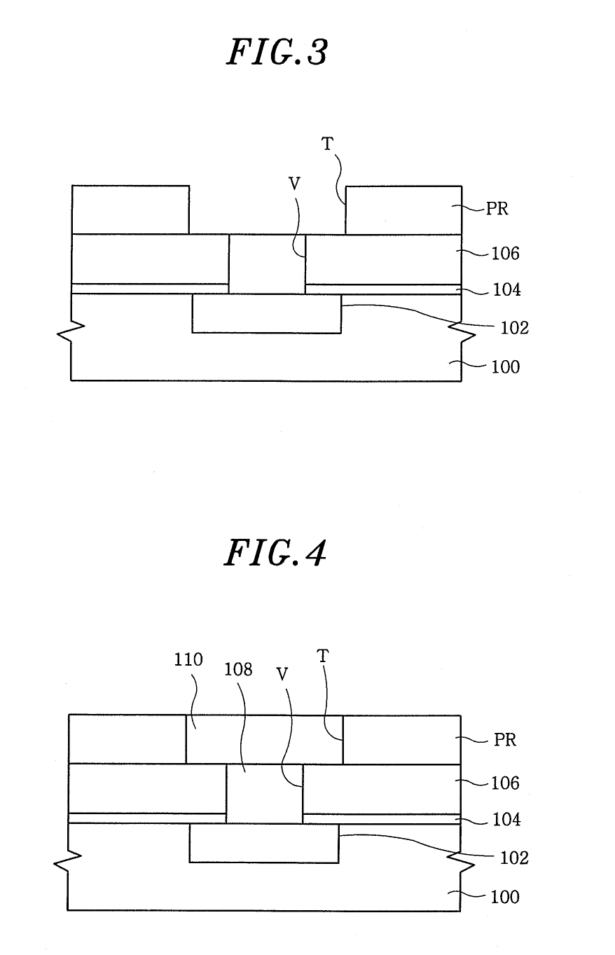

As illustrated in FIG. 3, a photoresist (PR) film is deposited over the first interlayer insulating film 106, and by performing an exposure and development process on the photoresist(PR) film, a trench T is formed to expose the via V. Here, the thickness of the PR film may be larger than that of the metal wiring by about 300 Å to about 500 Å.

As shown in FIG. 4, a metal is deposited to fill the trench T, thus obtaining a metal layer. Then, the structure is planarized through a polishing process, to obtain the metal wiring 110.

As illustrated in FIG. 5, the second interlayer insulating film 112 is deposited over the metal wiring 110 and the PR film. Then, by forming a photoresist pattern over the second interlayer insulating film 112 and then etching the second interlayer insulating film 112, aperture portions P are formed through which the PR film is partially exposed. The diameters of the aperture portions P are within a range from about 160 nm to about 200 nm.

Then, referring back to FIG. 1, the part of the PR film exposed through the aperture portions P is removed by ashing. By setting the etching time long enough, the PR film below the second interlayer insulating film 112 is removed.

FIG. 6 is a cross sectional view of a semiconductor device in accordance with embodiments. As illustrated in FIG. 6, an etching stop layer 204 and then a first interlayer insulating film 206 are deposited over a substrate 200. The substrate 200 may include individual devices (not shown) or a lower conductor 202.

The lower conductor 202 can be formed of copper (Cu), aluminum (Al), tungsten (W), silver (Ag), gold (Au), platinum (Pt), or the like. The etching stop layer 204 is made of SiN or the like, and the first interlayer insulating film 206 can be formed by depositing an organic or inorganic insulating material such as fluorine silicate glass (FSG), undoped silicate glass (USG), or tetra ethyl ortho silicate (TEOS), either in a single layer or multiple layers. Also, the first interlayer insulating film 206 can be formed of a low-k material such as a black diamond (BD) having a dielectric constant not greater than 3.0.

The lower conductor 202 of the substrate 200 is partially exposed by via V formed through the first interlayer insulating film 206. Formed on the first interlayer insulating film 206 are a barrier metal layer 208 and a metal wiring 210 which are electrically connected to the lower conductor 202 through the via V.

The barrier metal layer 208 serves to prevent diffusion of the metal wiring 210 into another layer such as the insulating film, and also serves to enhance the adhesion of the insulating film and the metal wiring 210. The metal wiring 210 is made of a conductive material such as copper having a low resistance.

A second interlayer insulating film 212 is formed over the metal wiring 210. The second interlayer insulating film 212 is in contact with the top surface of the metal wiring 210 protruded from the first interlayer insulating film 206 but does not contact the first interlayer insulating film 206. Accordingly, the second interlayer insulating film 212 is in a state where it is partially suspended over the first interlayer insulating film 206 and partially supported by the metal wiring 210. Thus, an empty space E exists between the first and the second interlayer insulating film 206 and 212. The second interlayer insulating film 212 has aperture portions P through which the first interlayer insulating film 206 is partially exposed.

With the empty space E between the first and the second interlayer insulating film 206 and 212 as described above, the dielectric constant of the semiconductor device decreases, so that parasitic capacitance can be reduced.

Below, a method for forming metal wiring of a semiconductor device having the described configuration will be explained with reference to FIGS. 7 to 11 together with FIG. 6. FIGS. 7 to 11 provide cross sectional views to describe a method for forming the metal wiring of the semiconductor device in accordance with embodiments.

As shown in FIG. 7, the etching stop layer 204 and the first interlayer insulating film 206 are deposited over the substrate 200. Then, the via V is formed through a selective etching process.

As illustrated in FIG. 8, a photoresist (PR) film is deposited over the first interlayer insulating film 206, and by performing an exposure and development process, a trench T is formed to expose the via V. Here, the thickness of the PR film may be larger than that of the metal wiring by about 300 Å to about 500 Å.

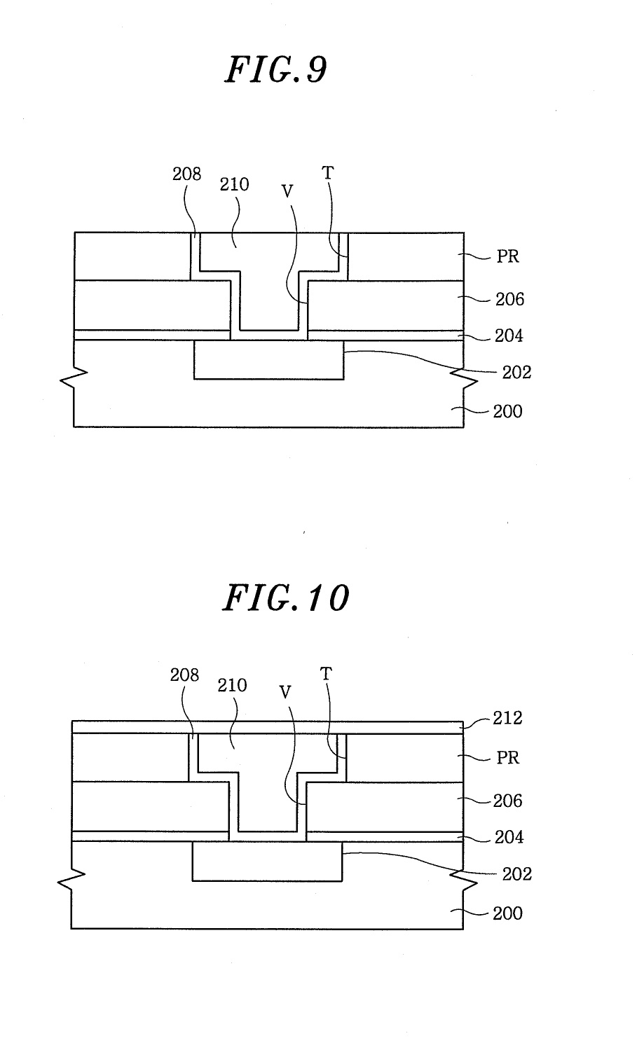

As shown in FIG. 9, a metal film 208 is deposited inside the trench T and the via V, and copper is deposited to fill the trench and the via defined by the metal layer 208, thus forming a copper layer. Thereafter, by planarizing the structure through a polishing process, the barrier metal layer 208 and the metal wiring 210 are obtained.

As shown in FIG. 10, the second interlayer insulating film 212 is deposited over the metal wiring 210 and the photoresist (PR) film. Then, by forming a photoresist pattern over the second interlayer insulating film 212 and etching the second interlayer insulating film 212, aperture portions P are formed through which the PR film is partially exposed. The diameters of the aperture portions P are within a range from about 160 nm to about 200 nm.

Referring back to FIG. 6, the part of the PR film exposed through the aperture portions P is removed by ashing. By setting the etching time long enough, the PR film below the second interlayer insulating film 212 is removed.

By using the photoresist film in the ways described above, the removal of the photoresist film may be accomplished relatively easily, forming an empty space in the area previously occupied by the photoresist film.

Thus, the formation of an air gap in the interlayer insulating film may be done easily, and an interlayer insulating film having a low dielectric constant may be obtained. It is therefore possible to provide a high quality semiconductor device with decreased RC delays.

It will be apparent to those skilled in the art that various modifications and variations can be made to embodiments. Thus, it is intended that embodiments cover modifications and variations thereof within the scope of the appended claims.

What is claimed is:

1. A semiconductor device comprising:
a semiconductor substrate;
a first interlayer insulating film formed over the semiconductor substrate and provided with a via allowing a connection from the semiconductor substrate to an upper layer;
a plug connected with the semiconductor substrate through the via;
a metal wiring formed over the first interlayer insulating film and being in contact with the plug; and
a second interlayer insulating film supported by the metal wiring and being partially suspended over the first interlayer insulating film.

2. The device of claim 1, wherein the plug and the metal wiring are formed of the same material.

3. The device of claim 1, wherein the second interlayer insulating film is provided with an aperture portion through which the first interlayer insulating film is exposed.

4. The device of claim 3, wherein the aperture portion has a diameter ranging from about 160 to about 200 nm.

5. A method for forming a semiconductor device, comprising:
forming a first interlayer insulating film over a semiconductor substrate;
forming a via through the first interlayer insulating film;
forming a plug by filling the via;
forming a photoresist film over the first interlayer insulating film;
forming a trench by performing an exposure and development process on the photoresist film, the trench allowing the plug to be exposed there through;
forming a metal wiring by filling the trench with a metal;
forming a second interlayer insulating film over the metal wiring;
forming an aperture portion in the second interlayer insulating film, the aperture portion allowing said photoresist film to be exposed there through; and
removing said photoresist film through the aperture portion.

6. The method of claim 5, wherein said photoresist film has a thickness larger than that of the metal wiring by about 300 Å to about 500 Å.

7. The method of claim 5, wherein the aperture portion has a diameter ranging from about 160 nm to about 200 nm.

8. A method for manufacturing a semiconductor device comprising:
forming a first interlayer insulating film over a semiconductor substrate;
forming a via through the first interlayer insulating film;
forming a photoresist film over the first interlayer insulating film;
forming a trench by performing an exposure and development of the photoresist film, the trench allowing the via to be exposed therethrough;
forming a metal wiring by filling the trench and the via;
forming a second interlayer insulating film over the metal wiring;
forming an aperture portion in the second interlayer insulating film, the aperture portion allowing said photoresist film to be exposed there through; and
removing said photoresist film through the aperture portion.

9. The method of claim 8, wherein said photoresist film has a thickness larger than that of the metal wiring by about 300 Å to about 500 Å.

10. The method of claim 8, wherein the aperture portion has a diameter ranging from about 160 nm to about 200 nm.
